(19) United States
(12) Patent Application Publication
(10) Pub. No.: US 2024/0114663 A1
(43) Pub. Date: Apr. 4, 2024

(54) COOLING SYSTEM AND METHOD OF MANUFACTURING A COOLING SYSTEM

(71) Applicant: Lear Corporation, Southfield, MI (US)

(72) Inventors: Ramon SANCHEZ ROVIRA, Valls (ES); Marcos BLANCO FIGUERAS, Valls (ES)

(73) Assignee: Lear Corporation, Southfield, MI (US)

(21) Appl. No.: 17/936,583

(22) Filed: Sep. 29, 2022

(51) Int. Cl. H05K 7/20

(52) U.S. Cl. CPC H05K 7/20409; H05K 7/20218

(57) ABSTRACT

A cooling system is described that includes a housing portion at least partially defining a cooling cavity, the housing portion including a member having multiple fins extending from a surface thereof into the cooling cavity. The cooling system also includes multiple walls, each of the walls supported in the cooling cavity by at least one of the fins. The walls are configurable, and a configuration of the walls establishes one of multiple paths for fluid flow through the cooling cavity.

### TECHNICAL FIELD

The present disclosure relates to a cooling system and a method of manufacturing a cooling system.

### BRIEF DESCRIPTION OF THE DRAWINGS

FIG. 1 is an exploded view of a non-limiting, exemplary embodiment of a cooling system according to the present disclosure;

FIGS. 2A and 2B are partial perspective views of a non-limiting, exemplary embodiment of a cooling system according to the present disclosure;

FIG. 3 is a perspective view of a non-limiting, exemplary embodiment of cooling system according to the present disclosure;

FIG. 4 is a partial exploded cross-sectional view of a non-limiting, exemplary embodiment of a cooling system according to the present disclosure;

FIG. 5 is a cross-sectional view of a non-limiting, exemplary embodiment of a cooling system according to the present disclosure;

FIGS. 6A-6C are perspective and top views of non-limiting, exemplary embodiments of non-limiting, exemplary components of a cooling system according to the present disclosure;

FIG. 7 is a perspective view of a non-limiting, exemplary embodiment of non-limiting, exemplary components of a cooling system according to the present disclosure;

FIG. 8 is a partial cross-sectional view of a non-limiting, exemplary embodiment of a cooling system according to the present disclosure;

FIG. 9 is a non-limiting, exemplary table illustrating displacement and other characteristics of a non-limiting, exemplary embodiment of a cooling system according to the present disclosure;

FIGS. 10A-10C are perspective views of a non-limiting, exemplary embodiment of a cooling system according to the present disclosure;

FIG. 11 is a perspective view of a non-limiting, exemplary embodiment of cooling system according to the present disclosure;

FIG. 12 is a cross-sectional view of a non-limiting, exemplary embodiment of a cooling system according to the present disclosure;

FIGS. 13A and 13B are non-limiting, exemplary tables illustrating exemplary pressure characteristics of a non-limiting, exemplary embodiment of a cooling system according to the present disclosure;

FIGS. 14A and 14B are non-limiting, exemplary tables illustrating exemplary thermal characteristics of a non-limiting, exemplary embodiment of a cooling system according to the present disclosure; and

FIGS. 15A and 15B are top views of non-limiting, exemplary embodiments of a cooling system according to the present disclosure.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, features, and elements have not been described in detail so as not to unnecessarily obscure aspects of the embodiments.

It is to be understood that the disclosed embodiments are merely exemplary and that various and alternative forms are possible. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ embodiments according to the disclosure.

“One or more” and/or “at least one” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the term “if” is, optionally, construed to mean “when” or “upon” or “in response to determining” or “in response to detecting,” depending on the context, Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

On-board Battery Chargers and any other electrification or electronic units require a cooling cavity. Currently, cooling cavities are part of a housing design, forcing the housing to be of aluminum. Moreover, each product has a cooling cavity designed specifically and as part of the product housing. This makes the housing complex and difficult and/or costly to manufacture. In that regard, cooling cavity inlet and outlet positions change in each commercial product. An internal cooling circuit layout must be designed each time accordingly. As a result, the cooling cavity cannot be re-used from product to product.

According to a non-limiting, exemplary embodiment of the present disclosure, a configurable cooling cavity is provided, based in a staggered pin-fin grid array in both a main cavity housing and a cover, where the internal cooling path layout is done with modular wall components which may be snap-fit to cavity walls and between them. Specific cooling designs are done based on modular components (cavity and walls), such as through a snap-fit process. Inlet and outlet spigots are drilled and fixed in place afterwards. Product families may profit from carry-over modular and/or configurable parts minimizing costs by economies of scale. Also, a product housing is simpler (cheaper) as the cavity is assembled after its manufacture, enabling even the use of plastic housings (and the cavity might be added during injection process). Such a modular cooling cavity may also be a carry-over in different products.

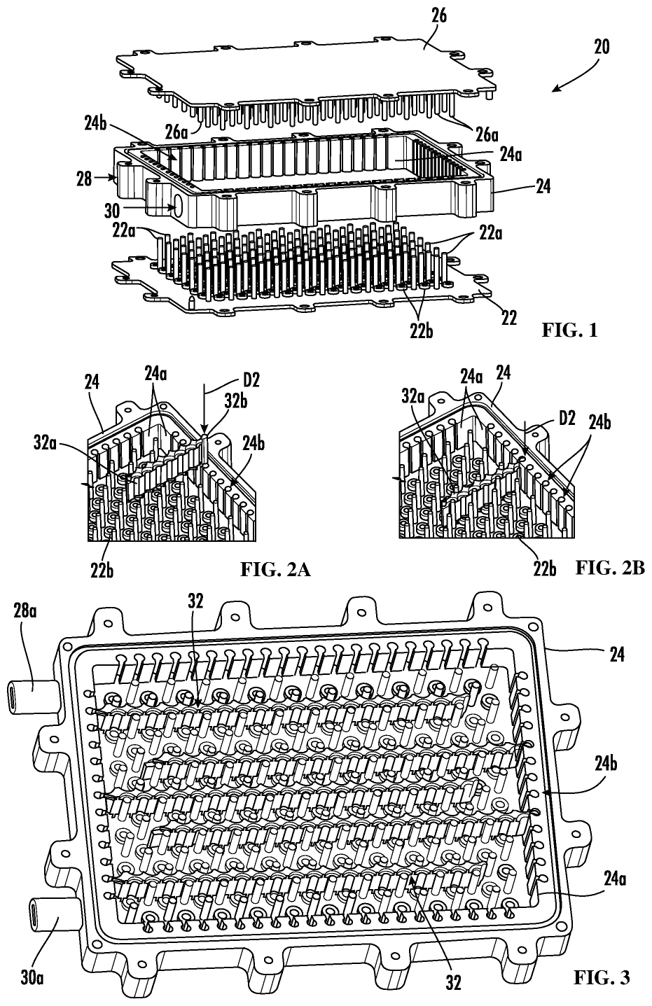

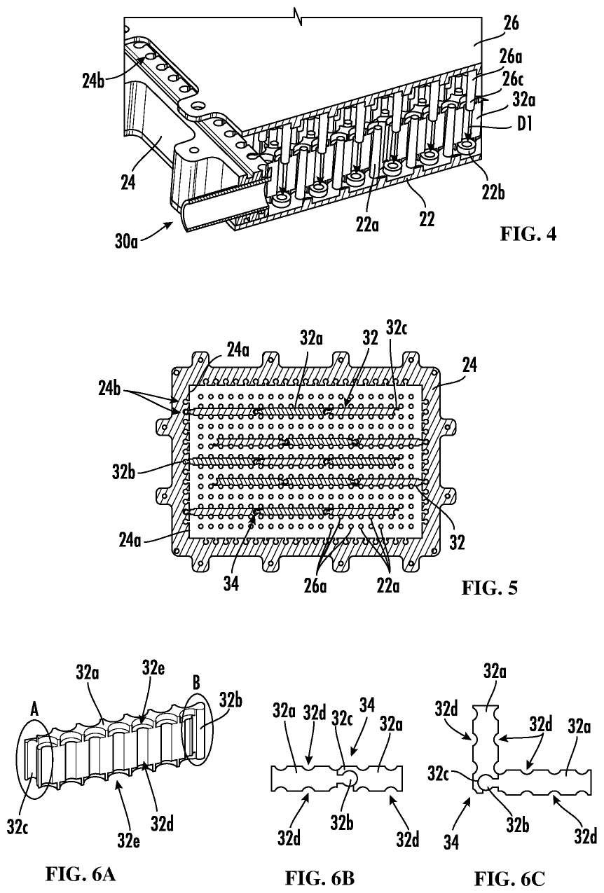

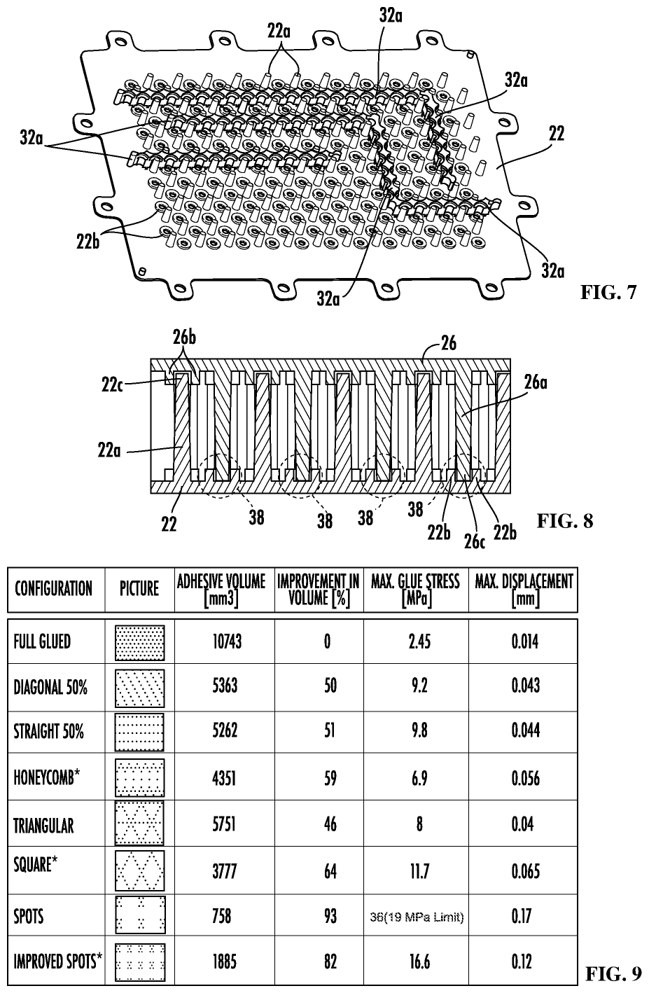

FIG. 1 is an exploded view of a non-limiting, exemplary embodiment of a cooling system according to the present disclosure. FIGS. 2A and 2B are partial perspective views of a non-limiting, exemplary embodiment of a cooling system according to the present disclosure. FIG. 3 is a perspective view of a non-limiting, exemplary embodiment of cooling system according to the present disclosure. FIG. 4 is a partial exploded cross-sectional view of a non-limiting, exemplary embodiment of a cooling system according to the present disclosure. FIG. 5 is a cross-sectional view of a non-limiting, exemplary embodiment of a cooling system according to the present disclosure. FIGS. 6A-6C are perspective and top views of non-limiting, exemplary embodiments of non-limiting, exemplary components of a cooling system according to the present disclosure. FIG. 7 is a perspective view of a non-limiting, exemplary embodiment of non-limiting, exemplary components of a cooling system according to the present disclosure. FIG. 8 is a partial cross-sectional view of a non-limiting, exemplary embodiment of a cooling system according to the present disclosure.

The embodiment of the present disclosure seen therein provides a cooling assembly 20 comprising a member or lower cover 22, a central frame 24, and another member or top or upper cover 26. While shown as a separate component, the central frame 24 may be integrally formed with the lower cover 22 or the upper cover 26. When assembled, the lower cover 22, central frame 24, and upper cover 26 form or define a cooling cavity, manifold, or plenum, through which a coolant may be circulated to provide cooling to an electronic unit, such as a vehicle on-board charger, to or with which the cooling system 20 is attached or associated. Each of the lower cover 22, central frame 24, and upper cover 26 may be formed from a metal or plastic material, in any combinations. In that regard, any cover with pin-fins (e.g., cover 22 with pin-fins 22a, or cover 26 with pin-fins 26a) comprises a thermally conductive material, which will typically be a metallic material. The central frame 24 has an opening or port or inlet 28 and an opening or port or outlet 30 formed therein (e.g., molded or drilled) for inlet and outlet spigots 28a, 30a (which may be glued, screwed, or otherwise fixed in or to inlet 28 and outlet 30, respectively) for a coolant to be circulated in the cooling cavity.

Each of the lower and upper covers 22, 26 includes a plurality of fins 22a, 26a extending therefrom into the cooling cavity to provide an increased surface area for contacting a coolant circulated in the cooling cavity and thereby improve cooling. While shown in the form or shape of pins, alternative forms or shapes for the fins 22a, 26a may be employed. The pin-fins 22a, 26a are also arranged in a staggered grid array. In that regard, the pin-fins 22a of the lower cover 22 are spaced apart in multiple rows, wherein the pin-fins 22a in one row are staggered relative to the pin-fins 22a in an adjacent row or rows. Similarly, the pin-fins 26a of the upper cover 26 are spaced apart in multiple rows, wherein the pin-fins 26a in one row are staggered relative to the pin-fins 26a in an adjacent row or rows. In such a fashion (best seen in FIG. 5), the pin-fins 22a of the lower cover 22 and the pin-fins 26a of the upper cover 26 are interleaved when the lower cover 22, central frame 24, and upper cover 26 are assembled. It is noted, however, that other arrangements of the pin-fins 22a, 26a may alternatively be employed. For example, the pin-fins 22a, 26a could be of half the height of the cavity and then not staggered between covers 22 and 26. In such a configuration, both covers 22, 26 could have a full array of pin-fins 22a, 26a with half heights and these could touch at their respective tips. Pin-fins 22a, 26a also have an axially symmetrical cross-section (e.g., circular, hexagonal, octagonal, etc.) in order to enable the configuration of walls 32a in any direction. Moreover, any number of pin-fins 22a, 26a may be employed, and pin-fins may be provided on only one of the lower cover 22 or the upper cover 26 to decrease cost, such as in an embodiment where all the electronic components are located only at one side of the cavity. In such an embodiment, the cover without pin-fins could alternatively comprise a plastic material. That is, there may be a single component which may be referred to as a “cover with pin-fins” that can be employed as a top cover 26 and/or as a bottom cover 22. In an embodiment as previously described where only one “cover with pin-fins” is needed, then a second component that may be referred to as a “cover without pin-fins” may be provided to complete the assembly. Still further, in an embodiment employing only one “cover with pin-fins” and employing a half-height pin-fin array extending from such a cover as previously described (i.e., electronic components located only in one side), then the “cover without pin fins” could be configured to “blind” at least a portion of a volume of the cooling cavity volume. That is, the “cover without pin-fins” could be configured with a surface that is depressed or pushed into the cooling cavity and that contacts, abuts, or touches the half-height pin-fins extending from the “cover with pin-fins” into the cooling cavity. In such an embodiment, positions of walls 32a may be adjusted to provide similar coolant or cooling liquid flow conditions.

Each of the lower and upper covers 22, 26 also includes a plurality of cavities or receptacles 22b, 26b formed therein or provide thereon. The receptacles 22b, 26b are interspersed among or between the pin-fins 22a, 26a in staggered grid arrays that complement those of the pin-fins 22a, 26a. As with the pin-fins 22a, 26a, however, any arrangement or number receptacles 22b, 26b may alternatively be employed, which need not match the arrangement and/or number of pin-fins 22a, 26a, and the receptacles may be provided on or in only one of the lower cover 22 or the upper cover 26. Each of the receptacles 22b of the lower cover 22 is configured to receive a corresponding pin-fin 26a of the upper cover 26. Similarly, each of the receptacles 26b of the upper cover 26 is configured to receive a corresponding pin-fin 22a of the lower cover 22. More particularly, as seen in FIGS. 4, when the upper cover 26 is assembled to the central frame 24 attached to the lower cover 22, the pin-fins 26a of the upper cover 26 move in the direction of arrows D1. As best seen in FIG. 8, a tip 26c of a pin-fin 26a of the upper cover 26 is received in a corresponding receptacle 22b of the lower cover 22. Similarly, a tip 22c of a pin-fin 22a of the lower cover 22 is received in a corresponding receptacle 26b of the upper cover 26.

Still referring to FIGS. 1-8, the cooling assembly 20 according to the embodiment shown includes a plurality of walls 32 which are configurable as desired, appropriate, sufficient, and/or suitable to establish any of a plurality of possible paths, circuits, or channels for coolant to be circulated through the cooling cavity from an inlet 28 or inlet spigot 28a to an outlet 30 or outlet spigot 30a, which may be located at different positions in or on the central frame 24 depending on design considerations (see FIGS. 3, 5, and 7). More specifically, a wall 32 includes one or more wall sections 32a. Each wall section 32a has an end (B) with a first attachment feature 32b and an end (A) with a second attachment feature 32c. In the embodiment shown, attachment feature 32b is a male attachment feature and attachment feature 32c is a female attachment feature. As a result, complementary attachment features 32b, 32c of two wall sections 32a are thereby configured to cooperate such that wall sections 32a can be attached, forming a joint 34, to form or create a longer or extended length wall 32. Such wall sections 32a may be attached in an in-line or straight-line configuration relative to each other (see FIG. 6B) or attached in an angled configuration relative to each other (see FIG. 6C), up to and including an angle of 90°, such that straight and/or angled paths may be established for coolant flow in the cooling cavity (see FIGS. 3, 5, and 7.) In such a fashion, the walls 32 and/or wall sections 32a are configurable such that any of a plurality of possible paths, circuits, or channels may be established for coolant to be circulated through the cooling cavity.

Moreover, each wall 32 is also attached to the central frame 24. In that regard, the central frame 24 includes an interior surface or wall 24a having a plurality of female attachment features 24b formed therein and configured to cooperate with male attachment features 32b of wall sections 32a, thereby allowing a wall section 32a (or a longer wall 32 constructed from multiple wall sections 32a) to be attached to the central frame 24. In that regard, as seen in FIGS. 2A and 2B, a male attachment feature 32b of a wall section 32a is inserted into a female attachment feature 24b of the central frame 24 in the direction of arrow D2. Alternatively, one or both of attachment features 24b, 32b may be formed of an elastically deformable material (e.g., plastic) such that the attachment features 24b, 32b may be snap-fit together. An embodiment may also employ both alternatives, i.e., insertion of a male attachment feature into a female attachment feature by “vertical” sliding, or snap-fitting a male attachment feature into a female attachment feature by “horizontal” pushing. In that regard, it is noted that only a plastic would enable both alternatives. Moreover, if frame 24 comprises a metallic material, there will be no deformation of the female side. It is also noted that the attachment features 32b, 32c at the ends of the walls 32a could be configured to slide into the attachment features 24a of the central frame 24 and to snap-fit to each other (i.e., 32b, 32c). It is still further noted that the interior surface or wall 24a of the central frame 24 may alternatively have male attachment features formed thereon configured to cooperate with female attachment features 32c of wall sections 32a.

Each wall 32, including each wall section 32a, is fixed and/or supported in the cooling cavity by one or more of the pin-fins 22a of the lower cover 22 and/or the pin-fins 26a of the upper cover 26. In the embodiment shown, each wall section 32a has recesses 32d formed therein to accommodate, cooperate with, and/or receive corresponding pin-fins 22a, 26a extending from the lower cover 22 and upper cover 26. Each wall section 32a also has recesses 32e formed therein to accommodate, cooperate with, and/or receive corresponding receptacles 22b, 26b formed in or on the lower cover 22 and upper cover 26. Once again, the wall 32, wall sections 32a, and/or interior wall 24a are configurable such that any of a plurality of possible paths, circuits, or channels may be established for coolant to be circulated through the cooling cavity.

The present disclosure thus provides a cooling system including a cold plate based on a staggered pin-fins grid array distributed between a main housing and a cover, where the cold plate may be a carry-over part from product to product. A coolant circuit layout, from a given inlet to outlet, is done with adding plastic walls inserted among the pin-fins array. The frame of the main housing has attachment features such as vertical slots in the internal side to insert plastic walls at any location.

As shown and described herein, the central frame 24 may be drilled to insert the spigots 28a, 30a in any specified position, depending upon the specific product requirements. The lower cover 26 may then be assembled or attached to the central frame 24. The cooling channel, circuit, or path is configured as desired, require, appropriate, and/or suitable by inserting, assembling, and/or interconnecting the plastic walls 32 among the pin fins 26a of the lower cover 26. Thereafter, the spigots 28a, 30a may be inserted into the central frame 24 and the top cover 22 may be assembled or attached to the central frame 24. In that regard, the upper cover 22 and lower cover 26 may be attached to the central frame 24 by friction welding, a structural adhesive, fasteners, or in any other known fashion. It is also noted that two or more cooling systems 20 of the present disclosure may be connected in series or in parallel to effectively provide a larger cooling cavity and thus greater cooling.

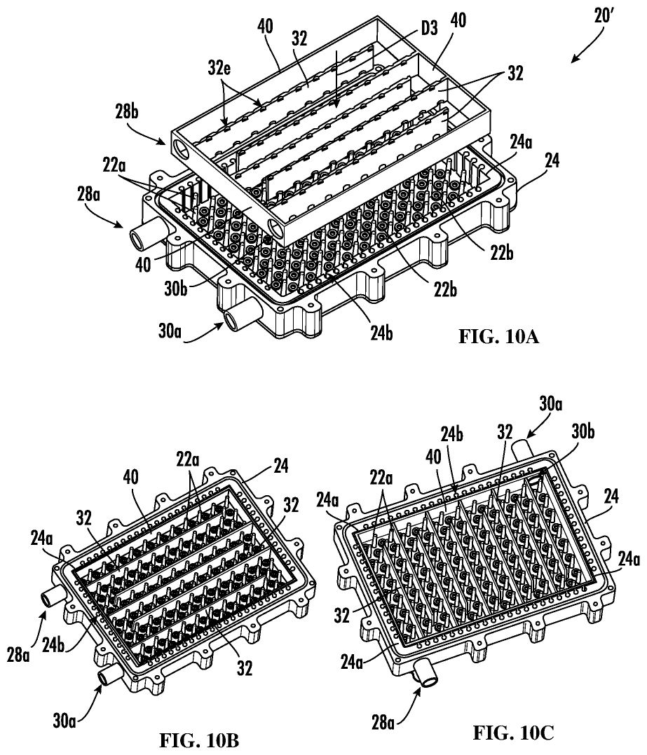

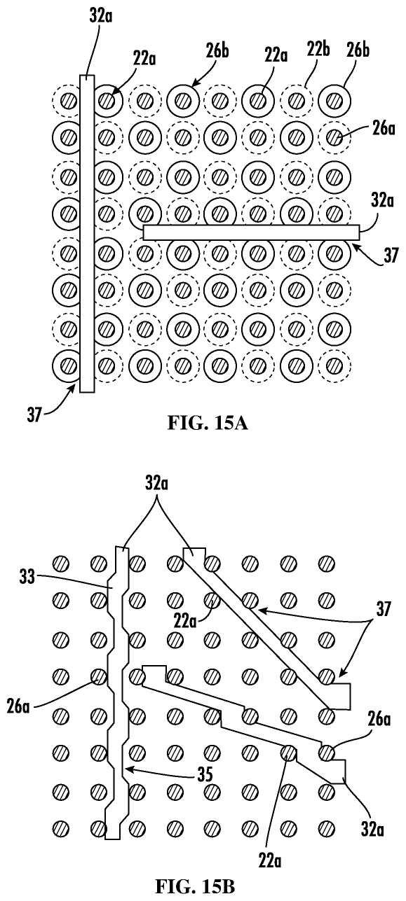

It is noted that placing the staggered pin-fins grid array in both the lower and upper covers 22, 26 ensures the same cooling performance in both sides of the cooling cavity. Where the two covers 22, 26 are the same component (i.e. “cover with pin-fins” as described previously), this is assured, including in the embodiment having a full array of half-height pin-fins. With an asymmetric use of covers (i.e., “cover with pin-fins” and “cover without pin-fins” as described previously), cooling performance on each side of the cooling cavity would differ. As previously described, the staggered pin-fins grid array also provides support and/or fixation columns to layout walls 32. In that regard, the walls 32 are inserted among the cooling pin-fins 22a, 26a that provide layout robustness. The walls 32 are modular and/or configurable, enabling several lengths and even 90° turns. In such a fashion, the lower cover 22, central frame 24, and/or upper cover 26 are carry-over parts dimensioned according to common internal structure (per product family). In one embodiment, a single wall module could be configured to enable assembling different paths (e.g., linear or at 90°). In an alternative embodiment, a number of lengths of walls or wall sections could be employed, which could include special shapes to enable walls at different angles (e.g., 45° or other angles). In still another embodiment, the shape of the walls or wall sections could be different. For example, a wall or wall section could be thinner so that it is held in place only by receptacles 22b and 26b, thereby letting the adjacent pin-fins 22a, 26a receive cooling liquid all around them. Examples of such embodiments are show in FIGS. 15A and 15B. As seen in the embodiments shown in FIG. 15A, walls or wall sections 32a are provided with a thinner or narrower width and are fixed or supported in the cooling cavity only by receptacles 22b, 26b of lower and upper covers 22, 26 (not shown) rather than by pin-fins 22a, 26a and/or central frame 24 (not shown) and/or frame 40 ((not shown) (see FIG. 10A)). As seen in the embodiments shown in FIG. 15B, walls or wall sections 32a are provided with particular shapes and or configurations (which may include projections 33 and/or indentations 35, 37 configured to cooperate with pin-fins 22a, 26a (e.g., abut or receive pin-fins 22a, 26a, or enable liquid flow around pin-fins 22a, 26a) to enable a greater number of options for configuring or for configurations of a cooling path, including cooling paths having angles anywhere between 0° and 90°.

As previously noted, FIG. 8 is a partial cross-sectional view of a non-limiting, exemplary embodiment of a cooling system according to the present disclosure. FIG. 9 is a non-limiting, exemplary table illustrating displacement and other characteristics of a non-limiting, exemplary embodiment of a cooling system according to the present disclosure.

Mechanically, the cooling system 20 will experience internal pressure during circulation of coolant in the cooling circuit. Flatness (i.e., displacement) of the lower and/or upper covers 22, 26 and mechanical integrity are assured by fixing or attaching, such as by gluing, one more of the tips 22c, 26c of pin-fins 22a, 26a of the lower cover 22 and/or upper cover 26 in or into corresponding cavities or receptacles 26b, 22b in the opposite upper cover 26 and/or lower cover 22. In the embodiment shown, the tips 26c of pin-fins 26a of the upper cover 26 are fixed (e.g., glued) at 38 into the receptacles 22b of the lower cover 22.

Non-limiting, exemplary patterns for glued pin-fins 22a and/or 26a are shown in the table of FIG. 9, each with a configuration and picture. As seen therein, based on adhesive volume (measured in cubic millimeters), a percentage improvement in such volume, maximum glue stress experienced during cooling system testing (measured in MegaPascals), and maximum displacement during cooling system testing (measured on millimeters), one or more optimal patterns may be identified. In that regard, “honeycomb”, “square”, and “improved spots” patterns or configurations provide better balance between mechanical performance and glue volume than do “full glued”, “diagonal 50%”, “straight 50%”, “triangular”, and “spots” patterns or configurations, with “improved spots” providing the best such balance. It is also noted that the “spots” pattern or configuration shown resulted in a maximum glue stress in excess of an acceptable limit.

According to another non-limiting, exemplary embodiment of the present disclosure, a modular cooling cavity is generated based in a staggered pin-fins grid array both in a main cavity and a cover. The internal wall layout is generated with an additional plastic part, to be inserted among the pin-fin array, with the pin-fins acting as supporting elements. Inlet and outlet spigots may be positioned afterwards. Because of modularity, this embodiment may be applied to families of products. This simplifies the product housing design and manufacture, as cooling cavity would be an addition component after the housing is manufactured, or even during the manufacturing process (in case a plastic housing was used). Such a cavity could then be carried-over between products, only changing the plastic frame with the internal coolant path layout (and later drilling and fixation of inlet and outlet spigots), providing cost reduction and making product housing simpler.

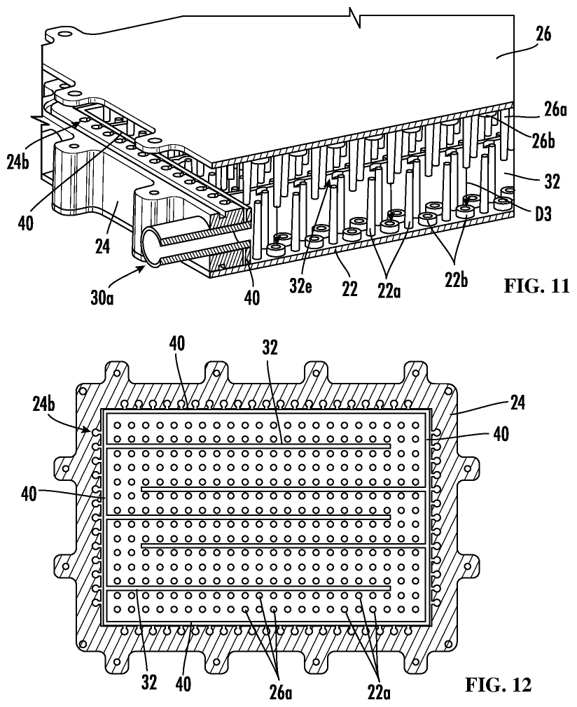

FIGS. 10A-10C are perspective views of a non-limiting, exemplary embodiment of a cooling system according to the present disclosure. FIG. 11 is a perspective view of a non-limiting, exemplary embodiment of cooling system according to the present disclosure. FIG. 12 is a cross-sectional view of a non-limiting, exemplary embodiment of a cooling system according to the present disclosure.

The embodiment of the present disclosure seen therein provides a cooling assembly 20′ comprising a member or lower cover 22, a central frame 24, and another member or top or upper cover 26. While shown as a separate component, the central frame 24 may be integrally formed with the lower cover 22 or the upper cover 26. When assembled, the lower cover 22, central frame 24, and upper cover 26 form or define a cooling cavity, manifold, or plenum, through which a coolant may be circulated to provide cooling to an electronic unit, such as a vehicle on-board charger, to or with which the cooling system 20′ is attached or associated. Each of the lower cover 22, central frame 24, and upper cover 26 may be formed from a metal or plastic material, in any combinations. As previously described, any cover with pin-fins (e.g., cover 22 with pin-fins 22a, or cover 26 with pin-fins 26a) comprises a thermally conductive material, which will typically be a metallic material. The central frame 24 has an opening or inlet 28 and an opening or outlet 30 formed therein (e.g., molded or drilled) for inlet and outlet spigots 28a, 30a for a coolant to be circulated in the cooling cavity.

Each of the lower and upper covers 22, 26 includes a plurality of fins 22a, 26a extending therefrom into the cooling cavity to provide an increased surface area for contacting a coolant circulated in the cooling cavity and thereby improve cooling. While shown in the form or shape of pins, alternative forms or shapes for the fins 22a, 26a may be employed. As previously described, pin-fins 22a, 26a also have an axially symmetrical cross-section to ensure that the same surface will be presented either to liquid circulating in one direction or the perpendicular direction (or at any angle). In that regard, pin-fins 22a, 26a with asymmetrical cross-sections (e.g., much wider in width in one direction than another) would enable liquid flow in one or more paths, but may inhibit liquid flow in another or other directions, or vice versa. Where asymmetrical cross-section pin-fins are employed, the freedom to position walls may be more limited and different areas with different orientations may be needed to provide for adequate cooling. The pin-fins 22a, 26a are also arranged in a staggered grid array. In that regard, the pin-fins 22a of the lower cover 22 are spaced apart in multiple rows, wherein the pin-fins 22a in one row are staggered relative to the pin-fins 22a in an adjacent row or rows. Similarly, the pin-fins 26a of the upper cover 26 are spaced apart in multiple rows, wherein the pin-fins 26a in one row are staggered relative to the pin-fins 26a in an adjacent row or rows. In such a fashion (best seen in FIG. 12), the pin-fins 22a of the lower cover 22 and the pin-fins 26a of the upper cover 26 are interleaved when the lower cover 22, central frame 24, and upper cover 26 are assembled. It is noted, however, that other arrangements of the pin-fins 22a, 26a may alternatively be employed. Moreover, any number of pin-fins 22a, 26a may be employed, and pin-fins may be provided on only one of the lower cover 22 or the upper cover 26 to decrease cost, provided no electronic components are to be cooled over the cover without pin-fins.

Each of the lower and upper covers 22, 26 also includes a plurality of cavities or receptacles 22b, 26b formed therein or provide thereon. The receptacles 22b, 26b are interspersed among or between the pin-fins 22a, 26a in staggered grid arrays that complement those of the pin-fins 22a, 26a. As with the pin-fins 22a, 26a, however, any arrangement or number receptacles 22b, 26b may alternatively be employed, which need not match the arrangement and/or number of pin-fins 22a, 26a, and the receptacles may be provided on or in only one of the lower cover 22 or the upper cover 26. Each of the receptacles 22b of the lower cover 22 is configured to receive a corresponding pin-fin 26a of the upper cover 26. Similarly, each of the receptacles 26b of the upper cover 26 is configured to receive a corresponding pin-fin 22a of the lower cover 22. More particularly, as seen in FIGS. 11, when the upper cover 26 is assembled to the central frame 24 attached to the lower cover 22, the pin-fins 26a of the upper cover 26 move in the direction of arrows D3. As a result, a tip 26c of a pin-fin 26a of the upper cover 26 is received in a corresponding receptacle 22b of the lower cover 22. Similarly, a tip 22c of a pin-fin 22a of the lower cover 22 is received in a corresponding receptacle 26b of the upper cover 26.

In the embodiment shown, a frame 40 is fashioned, formed, or provided, from which a plurality of walls 32 extend. The walls 32 are configurable as desired, appropriate, sufficient, and/or suitable to establish a path, circuit, or channel for coolant to be circulated through the cooling cavity from an inlet 28 or inlet spigot 28a to an outlet 30 or outlet spigot 30a, which may be located at different positions in or on the central frame 24 depending on design considerations (see FIGS. 10B and 10C). The frame 40 is inserted into the cooling cavity (i.e., the central frame 24 and lower cover 22 combination) such that the walls 32 extend therefrom into the cooling cavity to thereby establish a path, circuit, or channel for a coolant to be circulated in the cooling cavity. In that regard, once inserted, the frame 40 abuts the interior wall 24a of the central frame 24, following a perimeter of the cooling cavity formed thereby. The frame 40 has openings 28b, 30b formed therein, the locations of which correspond to inlet/outlet openings 28, 30 in the central frame 24 and inlet/outlet spigots 28a, 30a. In such a fashion, the frame 40 and walls 32 may be fashioned, formed, or provided in a plurality of modules, each configured to establish one of a plurality of possible paths, circuits, or channels for coolant to be circulated through the cooling cavity when a module comprising a frame 40 and walls 32 is inserted into the cooling cavity (see FIGS. 10B and 10C). It is also noted that, in the embodiment of FIGS. 10A-12, the attachment features 24b shown as formed in or on the interior wall 24a of the central frame 24 are unused and therefore may be deleted or omitted. If the attachment features 24b are deleted or omitted, then the walls 24a in frame 24 may be thinner, with less material, thus providing a cost saving when high series production is needed, using less material in frame 24 and reducing assembly time.

Each wall 32 is fixed and/or supported in the cooling cavity by one or more of the pin-fins 22a of the lower cover 22 and/or the pin-fins 26a of the upper cover 26. Alternatively, as described previously, the wall 32 may be proved with a thinner thickness, so that the wall 32 is only fixed by receptacles 22b, thereby enabling liquid flow around the pin-fins near the wall 32. In the embodiment shown, each wall 32 has recesses 32e formed therein to accommodate, cooperate with, and/or receive corresponding receptacles 22b, 26b formed in or on the lower cover 22 and upper cover 26. Once again, modules comprising a frame 40 and walls 32 are configurable such that any of a plurality of possible paths, circuits, or channels may be established for coolant to be circulated through the cooling cavity depending on the configuration of such a module or modules.

The present disclosure thus provides a cooling system including a cold plate based on a staggered pin-fins grid array distributed between a main housing and a cover, where the cold plate may be a carry-over part from product to product. A coolant circuit layout, from a given inlet to outlet, is done with an additional plastic part (e.g., frame and walls) inserted among the pin-fins array.

As shown and described herein, the central frame 24 may be drilled to insert the spigots 28a, 30a in any specified position, depending upon the specific product requirements. The lower cover 26 may then be assembled or attached to the central frame 24. The cooling channel, circuit, or path is configured as desired, require, appropriate, and/or suitable by inserting an additional part (e.g., frame 40 and walls 32) among the pin fins 26a of the lower cover 26 that will route a coolant. Thereafter, the spigots 28a, 30a may be inserted into the central frame 24 and the top cover 22 may be assembled or attached to the central frame 24. In that regard, the upper cover 22 and lower cover 26 may be attached to the central frame 24 by friction welding, a structural adhesive, fasteners, or in any other known fashion. It is also noted that two or more cooling systems 20 of the present disclosure may be connected in series or in parallel to effectively provide a larger cooling cavity and thus greater cooling.

It is noted that placing the staggered pin-fins grid array in both the lower and upper covers 22, 26 ensures the same cooling performance in both sides of the cooling cavity. As previously described, the staggered pin-fins grid array also provides support and/or fixation to layout walls 32 in frame 40. In that regard, the walls 32 are inserted among the cooling pin-fins 22a, 26a that provide layout robustness. The frame 40 and walls 32 are modular and/or configurable, in that a plurality of modules comprising a frame 40 and walls 32 laid out in different configurations provide for any of a plurality of paths, circuits, and/or channels to be established in a cooling cavity as desired or required according to a particular product design, such as depending on selected locations of inlet/outlet 28, 30. That is, the internal part or module (e.g., frame 40 and walls 32) will be designed according to the inlet and outlet positions for each application. In such a fashion, the lower cover 22, central frame 24, and/or upper cover 26 are carry-over parts dimensioned according to common internal structure (per product family).

The present disclosure thus provides multiple benefits, including a cooling cavity design that can be utilized for multiple programs or products, with design, validation and manufacturing tooling done only once. For example, a cooling circuit for a product may be redesigned to provide a new outlet position. Because the position of the outlet is different, the previous cooling circuit design cannot be re-used. A cooling circuit based on a modular and/or configurable concept according to the present disclosure permits re-usability of the design with minor changes. That is, the cooling cavity design may remain unchanged, but an internal part (e.g., frame 40 and walls 32) or parts (e.g., walls 32 including wall sections 32a) are customized or configured for the redesigned product.

The extruded nature of the present disclosure also permits the use of cold forging manufacturing that is cheaper than die casting. In that regard, the central frame 24 can be made of plastic, providing a cost saving. The top and bottom covers 22, 26 may be identical, i.e., the same part is used as top and bottom covers 22, 26. The present disclosure is also valid for double or single side cooling by replacing one of the covers having pin-fins with a flat cover, providing a cost saving. Thermal performance and pressure drop requirements can be also controlled with the internal plastic wall design. In that regard, path length and cross-section created by wall layout can be used to control pressure drop, while thermal performance can be controlled depending on the number of pins (in a cross-section) and fluid velocity. Moreover, any cooling circuit, channel, or path layout may be designed from modular and/or configurable components (e.g., walls 32 and wall sections 32a, or frame 40 and walls 32), and the similar parts (e.g., lower cover 22, central frame 24, and upper cover 26) carry-over to multiple projects. Further modularity may also be achieved by a combination of cooling cavity basic units joined together, such as by friction stir welding or a structural adhesive. The present disclosure is also applicable to any type of electronic unit requiring cooling or a cooling cavity (grouped by families of products with similar internal layouts).

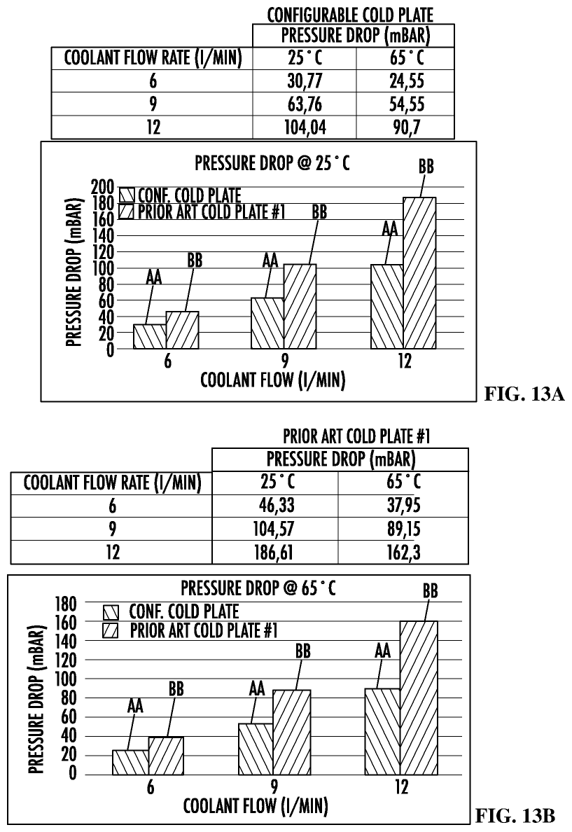

In testing of a cooling system according to the present disclosure to measure the cold plate pressure drop under different coolant flow rates and temperature scenarios, the pressure drop of the configurable cooling system of the present disclosure proved 39% lower than a die casting design according to the prior art. In that regard, FIGS. 13A and 13B are non-limiting, exemplary tables illustrating exemplary pressure characteristics of a non-limiting, exemplary embodiment of a cooling system according to the present disclosure. As seen therein, for coolant flow rates of 6, 9, and 12 liters/minute, the cooling system of the present disclosure consistently provides a lower pressure drop AA (measured in milliBars) than that of a prior art cold plate BB at coolant temperatures of both 25° C. and 65° C.

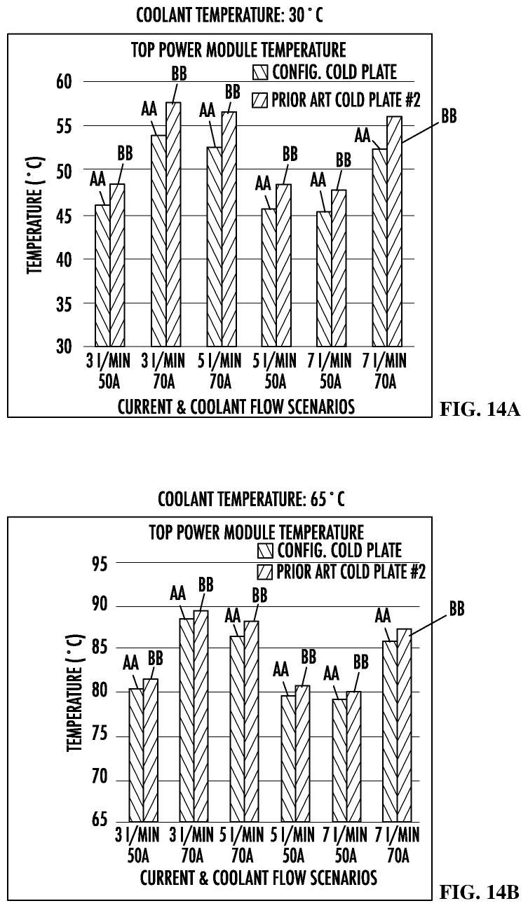

Moreover, in testing of a cooling system according to the present disclosure to measure the temperature of power modules attached on each side of the cold plate under different scenarios of current, coolant flow rate, and temperature, thermal performance of the configurable cooling system of the present disclosure proved 16% higher than a die casting design according to the prior art. In that regard, FIGS. 14A and 14B are non-limiting, exemplary tables illustrating exemplary thermal characteristics of a non-limiting, exemplary embodiment of a cooling system according to the present disclosure. As seen therein, for coolant flow rate and current scenarios of 3 liters/minute and 50 amps, 3 liters/minute and 70 amps, 5 liters/minute and 70 amps, 5 liters/minute and 50 amps, 7 liters/minute and 50 amps, and 7 liters/minute and 70 amps, the cooling system of the present disclosure consistently provides for a lower power module temperature AA (measured in ° C.) than a prior art cold plate BB at coolant temperatures of both 25° C. and 65° C.

The cooling system of the present disclosure thus offers better thermal performance and lower pressure drop values compared to cold plate designs in production. Changes of the cooling circuit and spigot positions are much cheaper than modifying die casting parts and can be accommodated by modifying an internal plastic part or parts and changing the drills position for the inlet/outlet. A cold forging manufacturing process of the pin-fin covers is also cheaper than a die casting process used for existing cold plates. The cooling assembly of the present disclosure also provides for re-usable part that can be employed in future products.
Item 1. According to an embodiment, the present disclosure provides a cooling system comprising a housing portion at least partially defining a cooling cavity, the housing portion comprising a member having a plurality of fins extending from a surface thereof into the cooling cavity, and a plurality of walls, each of the plurality of walls supported in the cooling cavity by at least one of the plurality of fins, wherein the plurality of walls is configurable, a configuration of the plurality of walls establishing one of a plurality of paths for fluid flow through the cooling cavity.
Item 2. In another embodiment, the present disclosure provides the cooling system of Item 1 further comprising a frame, wherein each of the plurality of walls extends from the frame and the frame is inserted in the cooling cavity.
Item 3. In another embodiment, the present disclosure provides the cooling system of Item 1 wherein the housing portion further comprises an interior wall having a wall attachment feature, one of the plurality of walls comprises an attachment feature, and the attachment feature of the one of the plurality of walls is attached to the wall attachment feature of the interior wall of the housing portion.
Item 4. In another embodiment, the present disclosure provides the cooling system of any of Items 1 or 3 wherein at least one of the plurality of walls comprises a plurality of wall sections, each of the plurality of wall sections having an attachment feature, and wherein an attachment feature of a first one of the plurality of wall sections is attached to an attachment feature of a second one of the plurality of wall sections.
Item 5. In another embodiment, the present disclosure provides the cooling system of any of Items 1, 3, or 4 wherein the first one of the plurality of wall sections is attached to the second one of the plurality of wall sections in an in-line configuration.
Item 6. In another embodiment, the present disclosure provides the cooling system of any of Items 1 or 3-5 wherein the first one of the plurality of wall sections is attached to the second one of the plurality of wall sections in an angled configuration.
Item 7. In another embodiment, the present disclosure provides the cooling system of any of Items 1-6 wherein the housing portion further comprises another member having a plurality of fins extending from a surface thereof into the cooling cavity.
Item 8. In another embodiment, the present disclosure provides the cooling system of any of Items 1-7 wherein the member comprises a plurality of receptacles formed on the surface thereof, each receptacle receiving a tip of one of the plurality of fins extending from the another member.
Item 9. In another embodiment, the present disclosure provides the cooling system of any of Items 1-8 wherein at least one tip is fixed to a corresponding one of the plurality of receptacles.
Item 10. In another embodiment, the present disclosure provides the cooling system of any of Items 1-9 wherein the housing portion includes an inlet port and an outlet port formed therein and the configuration of the plurality of walls establishes one of a plurality of paths for fluid flow through the cooling cavity from the inlet port to the outlet port.
Item 11. According to an embodiment, the present disclosure provides a method comprising forming a housing portion at least partially defining a cooling cavity, the housing portion comprising a member having a plurality of fins extending from a surface thereof into the cooling cavity, and inserting a plurality of walls into the cooling cavity, each of the plurality of walls supported in the cooling cavity by at least one of the plurality of fins, wherein the plurality of walls is configurable, a configuration of the plurality of walls establishing one of a plurality of paths for fluid flow through the cooling cavity.
Item 12. In another embodiment, the present disclosure provides the method of Item 11 wherein each of the plurality of walls extends from a frame and wherein inserting the plurality of walls comprises inserting the frame in the cooling cavity.
Item 13. In another embodiment, the present disclosure provides the method of Item 11 wherein the housing portion further comprises an interior wall having a wall attachment feature and one of the plurality of walls comprises an attachment feature, and wherein inserting the plurality of walls comprises attaching the attachment feature of the one of the plurality of walls to the wall attachment feature of the interior wall of the housing portion.
Item 14. In another embodiment, the present disclosure provides the method of any of Items 11 or 13 wherein at least one of the plurality of walls comprises a plurality of wall sections, each of the plurality of wall sections having an attachment feature, and the method further comprises attaching an attachment feature of a first one of the plurality of wall sections to an attachment feature of a second one of the plurality of wall sections
Item 15. In another embodiment, the present disclosure provides the method of any of Items 11, 13, or 14 further comprising attaching the first one of the plurality of wall sections to the second one of the plurality of wall sections in an in-line configuration.
Item 16. In another embodiment, the present disclosure provides the method of any of Items 11 or 13-15 further comprising attaching the first one of the plurality of wall sections to the second one of the plurality of wall sections in an angled configuration.
Item 17. In another embodiment, the present disclosure provides the method of any of Items 11-16 wherein the housing portion further comprises another member having a plurality of receptacles formed in a surface thereof and the method further comprises inserting a tip of one the fins extending from the surface of the member into one of the receptacles.
Item 18. In another embodiment, the present disclosure provides the method of any of Items 11-17 further comprising fixing at least one tip to a corresponding one of the plurality of receptacles.
Item 19. In another embodiment, the present disclosure provides the method of any of Items 11-18 further comprising forming an inlet port and an outlet port in the housing portion, wherein the configuration of the plurality of walls establishes one of a plurality of paths for fluid flow through the cooling cavity from the inlet port to the outlet port.
Item 20. According to an embodiment, the present disclosure provides a cooling system formed, manufactured, and/or assembled according to the method of any of Items 11-19.

While exemplary embodiments are described above, it is not intended that these embodiments describe all possible forms according to the disclosure. In that regard, the words used in the specification are words of description rather than limitation, and it is understood that various changes may be made without departing from the spirit and scope of the disclosure. Additionally, unless the context clearly indicates otherwise, the various features, elements, components, methods, procedures, steps, and/or functions of various implementing embodiments may be combined or utilized in any combination or combinations and/or may be performed in any order other than those specifically described herein to form further embodiments according to the present disclosure.

1. A cooling system comprising:
a housing portion at least partially defining a cooling cavity, the housing portion comprising a member having a plurality of fins extending from a surface thereof into the cooling cavity; and
a plurality of walls, each of the plurality of walls supported in the cooling cavity by at least one of the plurality of fins;
wherein the plurality of walls is configurable, a configuration of the plurality of walls establishing one of a plurality of paths for fluid flow through the cooling cavity.

2. The cooling system of claim 1 further comprising a frame, wherein each of the plurality of walls extends from the frame and the frame is inserted in the cooling cavity.

3. The cooling system of claim 1 wherein the housing portion further comprises an interior wall having a wall attachment feature, one of the plurality of walls comprises an attachment feature, and the attachment feature of the one of the plurality of walls is attached to the wall attachment feature of the interior wall of the housing portion.

4. The cooling system of claim 1 wherein at least one of the plurality of walls comprises a plurality of wall sections, each of the plurality of wall sections having an attachment feature, and wherein an attachment feature of a first one of the plurality of wall sections is attached to an attachment feature of a second one of the plurality of wall sections.

5. The cooling system of claim 4 wherein the first one of the plurality of wall sections is attached to the second one of the plurality of wall sections in an in-line configuration.

6. The cooling system of claim 4 wherein the first one of the plurality of wall sections is attached to the second one of the plurality of wall sections in an angled configuration.

7. The cooling system of claim 1 wherein the housing portion further comprises another member having a plurality of fins extending from a surface thereof into the cooling cavity.

8. The cooling system of claim 7 wherein the member comprises a plurality of receptacles formed on the surface thereof, each receptacle receiving a tip of one of the plurality of fins extending from the another member.

9. The cooling system of claim 8 wherein at least one tip is fixed to a corresponding one of the plurality of receptacles.

10. The cooling system of claim 1 wherein the housing portion includes an inlet port and an outlet port formed therein and the configuration of the plurality of walls establishes one of a plurality of paths for fluid flow through the cooling cavity from the inlet port to the outlet port.

11. A method comprising:
forming a housing portion at least partially defining a cooling cavity, the housing portion comprising a member having a plurality of fins extending from a surface thereof into the cooling cavity; and
inserting a plurality of walls into the cooling cavity, each of the plurality of walls supported in the cooling cavity by at least one of the plurality of fins;
wherein the plurality of walls is configurable, a configuration of the plurality of walls establishing one of a plurality of paths for fluid flow through the cooling cavity.

12. The method of claim 11 wherein each of the plurality of walls extends from a frame and wherein inserting the plurality of walls comprises inserting the frame in the cooling cavity.

13. The method of claim 11 wherein the housing portion further comprises an interior wall having a wall attachment feature and one of the plurality of walls comprises an attachment feature, and wherein inserting the plurality of walls comprises attaching the attachment feature of the one of the plurality of walls to the wall attachment feature of the interior wall of the housing portion.

14. The method of claim 11 wherein at least one of the plurality of walls comprises a plurality of wall sections, each of the plurality of wall sections having an attachment feature, and the method further comprises attaching an attachment feature of a first one of the plurality of wall sections to an attachment feature of a second one of the plurality of wall sections

15. The method of claim 14 further comprising attaching the first one of the plurality of wall sections to the second one of the plurality of wall sections in an in-line configuration.

16. The method of claim 14 further comprising attaching the first one of the plurality of wall sections to the second one of the plurality of wall sections in an angled configuration.

17. The method of claim 11 wherein the housing portion further comprises another member having a plurality of receptacles formed in a surface thereof and the method further comprises inserting a tip of one the fins extending from the surface of the member into one of the receptacles.

18. The method of claim 17 further comprising fixing at least one tip to a corresponding one of the plurality of receptacles.

19. The method of claim 11 further comprising forming an inlet port and an outlet port in the housing portion, wherein the configuration of the plurality of walls establishes one of a plurality of paths for fluid flow through the cooling cavity from the inlet port to the outlet port.

20. A cooling system assembled according to the method of claim 11.
